(19) United States
(12) Patent Application Publication
(10) Pub. No.: US 2010/0079133 A1
(43) Pub. Date: Apr. 1, 2010

(54) HEAT SINK MOUNTING STRUCTURE AND ELECTRONIC APPARATUS

(76) Inventor: Hirotaka Kadoshima, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/566,489

(22) Filed: Sep. 24, 2009

(30) Foreign Application Priority Data
Sep. 29, 2008 (JP) 2008-250234

(51) Int. Cl. G01R 19/155; H05K 7/20

(52) U.S. Cl. 324/157; 361/720

(57) ABSTRACT

According to one embodiment, a heat sink mounting structure for mounting a heat sink for radiating heat from a heat-generating part on a printed circuit board in the heat-generating part, comprises a hook, a conductive clip, a power supply and a detector. The hook is formed close to the heat-generating part. The conductive clip presses and secures the heat sink to the heat-generating part by a stress produced when hanging on the hook. The power supply applies a voltage to the clip. The detector detects detachment of the heat sink from the heat-generating part, when no current flows from the power supply to the clip through the hook.

### CROSS-REFERENCE TO RELATED APPLICATIONS

This application is based upon and claims the benefit of priority from Japanese Patent Application No. 2008-250234, filed Sep. 29, 2008, the entire contents of which are incorporated herein by reference.

### BACKGROUND

1. Field

One embodiment of the invention relates to a technique of mounting a heat sink to promote heat radiation in an electronic device such as a central processing unit (CPU).

2. Description of the Related Art

As is well known, a device such as a CPU incorporated in a computer generates heat during operation. Extreme heat generation may cause device malfunction or destruction. A heat sink having a large surface area and high thermal conductivity is generally mounted on a device to avoid such problems (refer to Jpn. Pat. Appln. KOKAI Publication No. 2-298053 (reference 1)).

A heat sink may be dislodged from a heat-generating part by vibration during transportation or installation of a computer. This is unnoticeable from the outside and cannot be left unrectified. In particular, in a server or other basic device such as a communication unit operating continuously, physical detachment of a heat sink causes a computer to go down unexpectedly. This may cause a system connected to the computer through a network to fail. It can be said that a heat sink is an Achilles heel in computer system operation. It is required to immediately detect detachment of a heat sink.

Jpn. Pat. Appln. KOKAI Publication No. 9-148035 (reference 2) discloses a technique of detecting detachment of a substrate from a slot by detecting discontinuation of a connector pin in a structure that a substrate connector is inserted into a slot of a motherboard, for example. However, this technique cannot be applied to detection of detachment of a heat sink. A CPU does not have a slot to insert a heat sink, and a heat sink is usually not energized (to prevent a malfunction of a CPU). Connection between devices having electronic functions can be detected by the technique of the reference 2. However, a heat sink is a part made only by shaping metallic material, and has no electronic functions.

Therefore, a technique of immediately detecting detachment of a heat sink from a heat-generating part is required, and is a high priority in the field of precision instruments such as a computer.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary diagram showing an embodiment of a system having an electronic apparatus according to the present invention;

FIG. 2 is a block diagram of an example of an electronic apparatus according to the invention;

FIG. 3 is a perspective view of a first embodiment of a heat sink mounting structure according to the invention;

FIG. 4 is a perspective view showing a state in which a heat sink 2 is detached relative to the state of FIG. 3;

FIG. 5 is a perspective view of an existing heat sink mounting structure for comparison;

FIG. 6 is a perspective view of an existing heat sink mounting structure for comparison; and

FIG. 7 is a perspective view of a second embodiment of a heat sink mounting structure according to the invention.

### DETAILED DESCRIPTION

Various embodiments according to the invention will be described hereinafter with reference to the accompanying drawings. In general, according to one embodiment of the invention, there is provided a heat sink mounting structure for mounting a heat sink for radiating heat from a heat-generating part on a printed circuit board in the heat-generating part, comprises a hook, a conductive clip, a power supply and a detector. The hook is formed close to the heat-generating part. The conductive clip presses and secures the heat sink to the heat-generating part by a stress produced when hanging on the hook. The power supply applies a voltage to the clip. The detector detects detachment of the heat sink from the heat-generating part, when no current flows from the power supply to the clip through the hook.

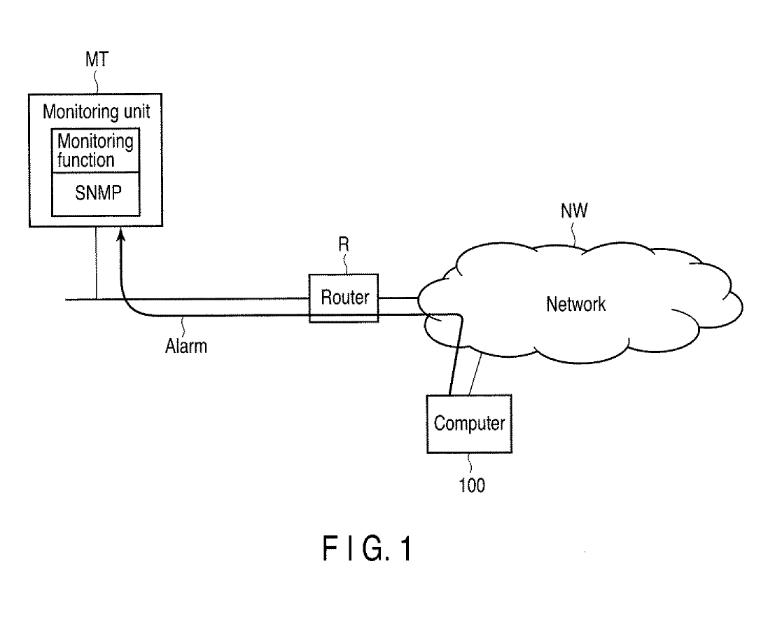

According to an embodiment, FIG. 1 is a system diagram showing an embodiment of a system having an electronic apparatus according to the present invention. In FIG. 1, a computer 100 as an electronic apparatus belongs to a network NW, and is connected to a monitoring unit MT. The network NW is Internet Protocol (IP) network, for example.

The monitoring unit MT is a server that functions as a higher-order unit of the computer 100, and remotely monitors the states of the computer 100 based on the information reported in the form of an alarm, for example. The protocol used for monitoring is typically the Simple Network Management Protocol (SNMP), but not limited to SNMP.

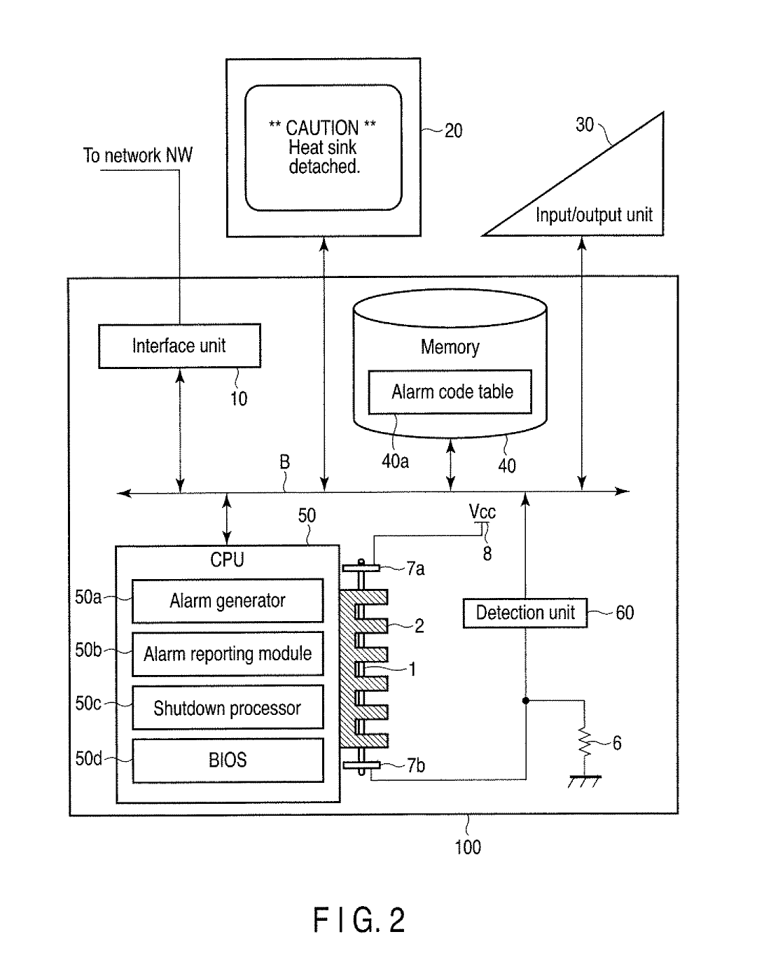

FIG. 2 is a block diagram of an example of the computer 100 according to the embodiment. The computer 100 is a server or a communication unit, for example. The computer 100 has an interface unit 10, a display unit 20, an input/output unit 30, a memory 40, and a CPU 50. The interface unit 10 is connected to the network NW, and used for transfer of packets. The display unit 20 and input/output unit 30 provide user interface environment using graphical user interface (GUI).

The CPU 50 is provided with a heat sink 2. The heat sink 2 is secured with a fixing clip with conductivity just like being pressed to the CPU 50. Both ends of the fixing clip are hung on hooks 7a and 7b provided close to the CPU 50. Thereby, when the heat sink 2 is secured, the fixing clip 1 is subjected to tension.

The fixing clip 1 is supplied with a certain voltage Vcc from a substrate power supply 8, forming a closed circuit from the power supply 8 to a detection unit 60 through the fixing clip 1 and hook 7b. A pull-down resistor 6 is connected parallel to this closed circuit. The detection unit 60 is a latch circuit to detect the voltage at both ends of the pull-down resistor 6, for example. When detecting that the voltage drops to zero, the detection unit 60 informs the CPU 50 of the fact through an internal bus B. Then, a basic input/output system (BIOS) 50d detects that the voltage drops to zero.

When the closed circuit is opened, no current flows in this circuit and the voltage drop in the pull-down resistor is zero, that is, the voltage drop cannot be detected. This means that the fixing clip 1 is disengaged from the hook 7B (or 7a), and the heat sink 2 is detached from the CPU 50. The detection unit 60 detects the detachment of the heat sink 2 by detecting that no current flows in the fixing clip 1, or that the voltage has dropped to zero. The BIOS 50d detects the detachment of the heat sink 2 by a signal from the detection unit 60, and reports it to a higher-order layer processing function.

In addition to the basic functions such as the BIOS 50d, the CPU 50 has an alarm generator 50a, an alarm reporting module 50b, and a shutdown processor 50c as processing functions according to this embodiment.

When receiving the notice that the heat sink is detached from the BIOS 50, the alarm generator 50a generates alarm information to inform the monitoring unit MT of the fact. The alarm generator 50a refers to an alarm code table 40a stored in a memory 40, and transmits a byte-code corresponding to the detachment of the heat sink 1 to the alarm reporting module 50b. For example, in SNMP, alarm information is generated as SNMP TRAP.

The alarm reporting module 50b reports this packet to the monitoring unit MT from the interface unit 10 through an external network. The alarm reporting module 50b displays an alarm message (CAUTION) “Heat sink detached.” on the display unit 20 to draw an operator's attention.

When receiving the notice that the heat sink is detached from the BIOS 50d, the shutdown processor 50c saves the registry contents, and shuts down the apparatus, that is, the computer 100. In some cases, the shutdown processor 50c may shuts down the computer without saving the registry contents.

### First Embodiment

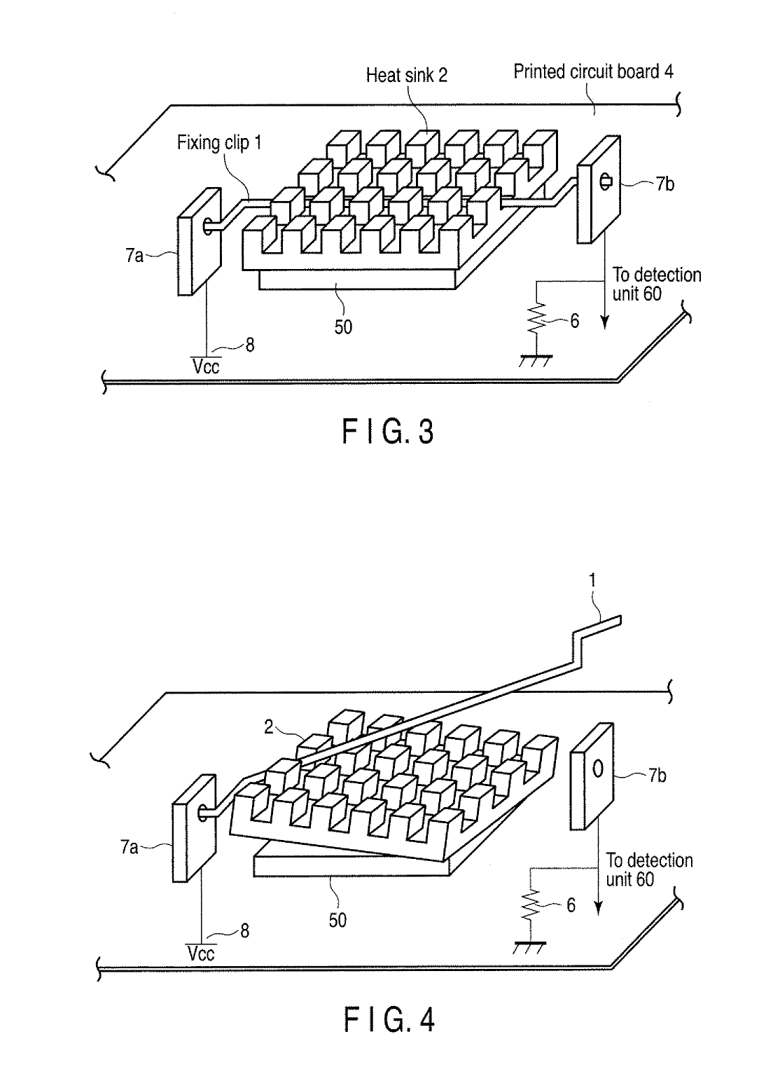

FIG. 3 is a perspective view of a first embodiment of a heat sink mounting structure according to the invention. FIG. 3 shows the state in which the heat sink is normally pressed and secured to the CPU 50. In this state, both ends of the fixing clip 1 in the longitudinal direction are hung on the hooks 7a and 7b, and the fixing clip 1 is subjected to tension.

To make the fixing flip 1 appropriately elastic, the fixing clip 1 may be made of bronze or steel wire. It is preferable to electrically insulate the part of the fixing clip 1 contacting the heat sink 2 by means of insulating material such as vinyl or enamel paint. Insulation can be ensured by coating paint on the heat sink 2. It is more dependable to cover the fixing clip 1 with an insulating sheath.

The hooks 7a and 7b are formed in the proximity of the socket of the CPU 50 on a printed circuit board 4. The hooks 7a and 7b may be formed as one piece with the CPU socket. A voltage Vcc is taken from the substrate power supply 8 provided on a power supply line of the printed circuit board 4. The voltage Vcc is applied to the closed circuit through the hook 7a, fixing clip 1, and hook 7b, and causes a certain voltage drop in the pull-down resistor 6.

FIG. 4 is a perspective view showing a state in which the heat sink 2 is detached relative to the state of FIG. 3. Detachment of the heat sink 2 from the CPU 50 means detachment of the fixing clip 1 from the hooks 7a and 7b. In this state, the closed circuit is opened, and the voltage drop in the pull-down resistor 6 cannot be detected. This state is detected by the detection unit 60 of FIG. 2, and is reported to the CPU 50, and an alarm is emitted, caution is displayed, or the computer is shut down. Thereby, the system function is stopped, temperature increase is stopped, and the electronic apparatus is protected from thermal damage.

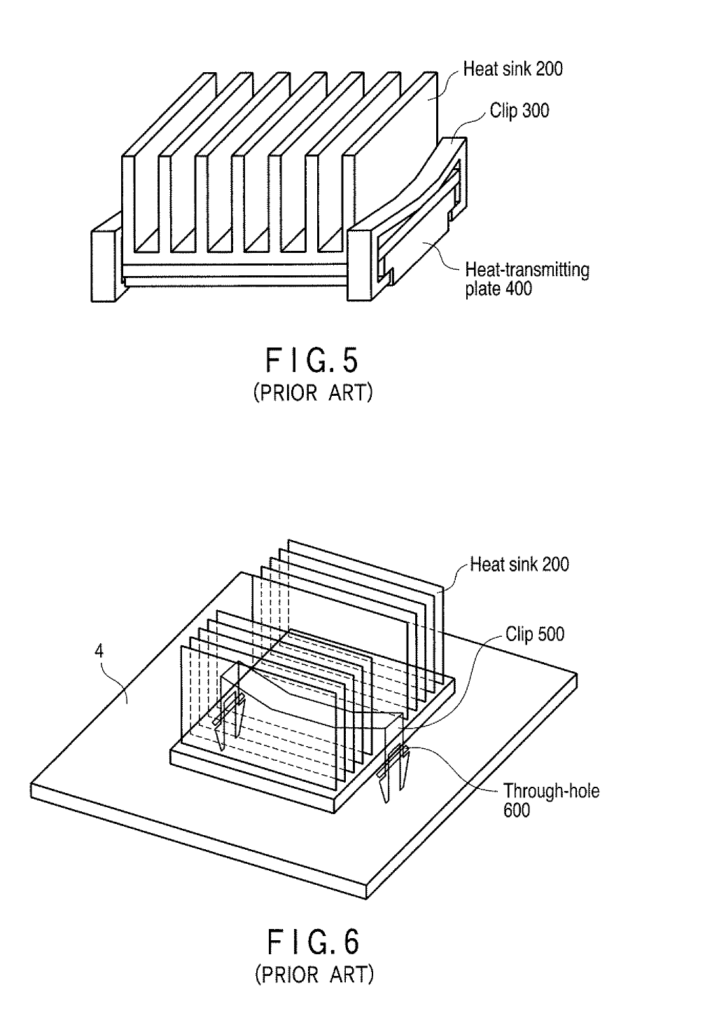

FIGS. 5 and 6 are perspective views of an existing heat sink mounting structure for comparison. In FIG. 5, a heat sink 200 is combined with another part (a heat-transmitting plate 400), and secured with a clip 300 made of resin material. In FIG. 6, a clip 500 is inserted into a through-hole 600 formed on the substrate 4, and the heat sink is hung on the clip. In either structure, a heat sink is merely secured, and a mechanism to detect detachment of a heat sink is not provided.

In contrast, in the first embodiment, the hooks 7a and 7b for hanging the conductive and elastic fixing clip 1 are formed close to the CPU 50. The heat sink 2 is pressed and secured to the CPU 50 by the stress produced by hanging the fixing clip 1 on the hooks 7a and 7b, so that a closed electrical circuit is formed in this state. The voltage Vcc from the substrate power supply 8 is applied to the closed circuit, and detachment of the heat sink from the hooks 7a and 7b of the fixing clip 1 is detected by detecting whether the voltage drops in the pull-down resistor 6. When the detachment of the heat sink is detected by the detection unit 60, the fact is reported to the CPU 50, and the computer is immediately shut down.

As described above, the detachment of the heat sink can be electronically detected by making the member securing the heat sink 2 conductive and measuring the conductivity. Therefore, when the heat sink is detached, it can be immediately and systematically detected. Further, in the first embodiment, when the detachment is detected, the computer is shut down. This prevents damage to or destruction of components or a fatal error such as data loss. Further, the detachment of the heat sink 2 is displayed on the display unit 20, and reported to the monitoring unit MT by an alarm, and the system operator can immediately take appropriate action. Therefore, it is possible to provide a heat sink mounting structure and an electronic apparatus, which can immediately and securely detect detachment of a heat sink.

### Second Embodiment

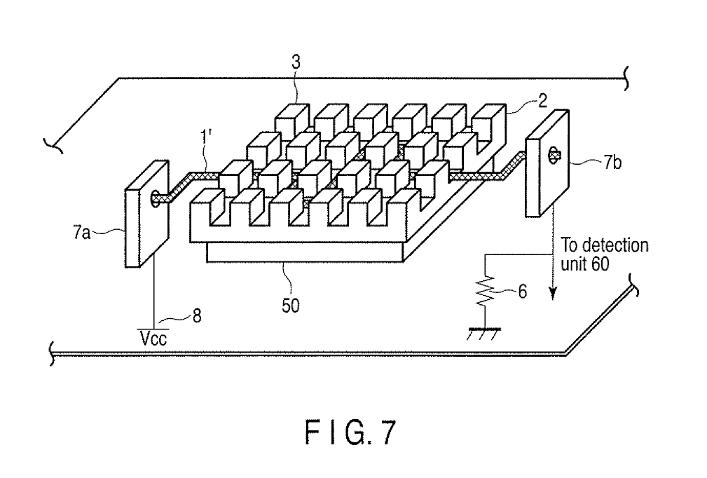

FIG. 7 is a perspective view of a second embodiment of a heat sink mounting structure according to the invention. In FIG. 7, the parts common to FIG. 3 are given the same reference numbers, and only the different parts will be explained hereinafter. The heat sink 2 has a projection 3 formed on a side opposing to a side pressed to the CPU 50, to increase the heat radiation effect.

In FIG. 7, a fixing clip (denoted by reference number 1′) is bent to fit with the projection 3 of the heat sink 2. Namely, a rod-like member is bent avoiding a projected portion of the projection 3 of the heat sink 2, and is formed as a fixing clip 1′. With this structure, the fixing clip 1′ fits with the projection 3 in the state being hung on the hooks 7a and 7b, and prevents horizontal displacement of the heat sink 2 (in the direction parallel to the pressing surface). Further, coplanarity of the heat sink 2 can be ensured.

The invention is not limited to the first and second embodiments. For example, the heat sink 1 is not limited to the CPU 50. The heat sink 1 may be any electronic device (semiconductor device) generating heat upon functioning, such as an integrated circuit (IC) and a large-scale integrated circuit (LSI). When the heat sink is detached, the computer may not be immediately shut down, but least necessary functions may be continued in a range not causing thermal runaway.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A heat sink mounting structure for mounting a heat sink for radiating heat from a heat-generating part on a printed circuit board in the heat-generating part, comprising:
a hook formed close to the heat-generating part;
a conductive clip which presses and secures the heat sink to the heat-generating part by a stress produced when hanging on the hook;
a power supply to apply a voltage to the clip; and
a detector configured to detect detachment of the heat sink from the heat-generating part, when no current flows from the power supply to the clip through the hook.

2. The heat sink mounting structure of claim 1, wherein the detector has a pull-down resistor connected to a closed circuit formed from the power supply to the clip through the hook, and detects the detachment when a voltage drop in the pull-down resistor is zero.

3. The heat sink mounting structure of claim 1, wherein the heat sink has a projection formed on a side opposing to a side pressed to the heat-generating part, and the clip is made of a rod-shaped member bent to fit with the projection in a state being hanged on the hook.

4. The heat sink mounting structure of claim 1, wherein the heat-generating part is a semiconductor device.

5. The heat sink mounting structure of claim 1, further comprising an insulating member to electrically insulate a part where the clip contacts the heat sink.

6. The heat sink mounting structure of claim 1, wherein the insulating member is a sheathing material to cover the clip.

7. An electronic apparatus comprising:
an electronic device which is provided on a printed circuit board, and generates heat;
a heat sink for radiating the electronic device;
a hook formed close to the electronic device;
a conductive clip which presses and secures the heat sink to the electronic device by a stress produced when hanging on the hook;
a power supply to apply a voltage to the clip; and
a detector configured to detect detachment of the heat sink from the heat-generating part, when no current flows from the power supply to the clip through the hook.

8. The electronic apparatus of claim 7, wherein the detector has a pull-down resistor connected to a closed circuit formed from the power supply to the clip through the hook, and detects the detachment when a voltage drop in the pull-down resistor is zero.

9. The electronic apparatus of claim 7, wherein the heat sink has a projection formed on a side opposing to a side pressed to the heat-generating part, and the clip is made of a rod-shaped member bent to fit with the projection in a state being hanged on the hook.

10. The electronic apparatus of claim 7, wherein the electronic device is provided as a central processing unit (CPU).

11. The electronic apparatus of claim 7, further comprising a display unit which displays the detachment when the detachment is detected by the detector.

12. The electronic apparatus of claim 7, further comprising:
an alarm generator which generates alarm information indicating the detachment when the detachment is detected by the detector, and
an alarm reporting module configured to report the alarm to a higher-order unit

13. The electronic apparatus of claim 7, further comprising a shutdown processor configured to shut down the apparatus when the detachment is detected by the detector.
